(19) United States
(12) Patent Application Publication
(10) Pub. No.: US 2008/0286896 A1
(43) Pub. Date: Nov. 20, 2008

(54) METHOD FOR MANUFACTURING IMAGE SENSOR

(76) Inventor: Chung-Kyung Jung, Anyang-si (KR)

Correspondence Address: SHERR & VAUGHN, PLLC, 620 HERNDON PARKWAY, SUITE 200, HERNDON, VA, 20170, US

(21) Appl. No.: 12/119,589

(22) Filed: May 13, 2008

(30) Foreign Application Priority Data
May 16, 2007 (KR) 10-2007-0047597

(51) Int. Cl. B29D 11/00; H01L 31/0232

(52) U.S. Cl. 438/70; 216/26; 257/E31.127

(57) ABSTRACT

A method for manufacturing an image sensor including forming an interlayer dielectric layer on a substrate including a photo diode; forming a color filter layer on the interlayer dielectric layer; forming an oxide film on the color filter layer; forming a plurality of micro lens patterns spaced apart on the oxide film; forming an oxide-based micro lens having a predetermined curvature by etching the oxide film using the micro lens pattern as a mask; and cleaning the micro lens patterns with a peroxosulfuric acid mixing solution.

The present application claims priority under 35 U.S.C. §119 to Korean Patent Application No. 10-2007-0047597 (filed May 16, 2007), which is hereby incorporated by reference in its entirety.

### BACKGROUND

An image sensor is a semiconductor device for converting optical images into electrical signals. An image sensor may be classified as a charge coupled device (CCD) or a complementary metal oxide silicon (CMOS) image sensor (CIS). The CMOS image sensor includes a photo diode and a MOS transistor formed in a unit pixel to sequentially detect electrical signals of each unit pixel in a switching manner, thereby implementing images.

Image sensors may utilize technology that makes the fill factor of a region occupied by the photo diode in the overall area of the image sensor large or changes a path of light incident on a region other than the photo diode to focus it onto the photo diode, thereby increasing photo sensitivity. A representative example of the focusing technology forms a micro lens.

A method for forming a micro lens during a process for manufacturing the image sensor may generally implement a micro photo process using a special photo resist for the micro lens and then a reflowing process. The amount of photo resist lost when reflowing the photo resist, however, may be lost thereby causing a gap (G) between the micro lenses. Therefore, the amount of light incident on the photo diode is reduced, thereby causing image defects. Morerover, when a micro lens is composed of organic substances, particles caused when performing a wafer sawing in a post-processing, such as a package or a bump in a semiconductor chip mount process, etc. may damage the micro lens or otherwise may become attached to the micro lens thereby causing image defects. The existing micro lens may have a difference in a focal length to a horizontal axis and a diagonal axis when forming the micro lens so that a crosstalk phenomenon to neighboring pixels may be caused.

### SUMMARY

Embodiments relate to a method for manufacturing an image sensor that forms a micro lens using an oxide film.

Embodiments relate to a method for manufacturing an image sensor that can remove a photo resist without attacking the oxide film of a micro lens in implementing the micro lens.

Embodiments relate to a method for manufacturing an image sensor that minimizes a gap between neighboring micro lenses.

Embodiments relate to a method for manufacturing an image sensor that can include at least one of the following steps: forming an interlayer dielectric layer on a substrate including a photo diode; forming a color filter layer on the interlayer dielectric layer; forming an oxide film on the color filter layer; forming a plurality of micro lens patterns having a predetermined interval on the oxide film; forming an oxide film micro lens having predetermined curvature by etching the oxide film using the micro lens as a mask; and then cleaning the micro lens patterns with peroxosulfuric acid mixing solution.

### DRAWINGS

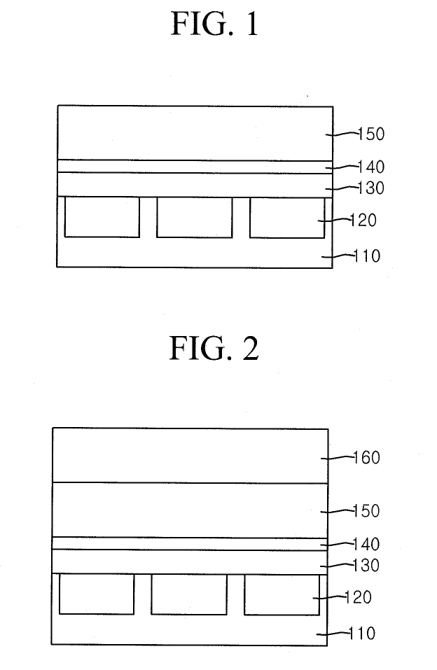

Example FIGS. 1 to 7 illustrate an image sensor, in accordance with embodiments.

### DESCRIPTION

In accordance with embodiments, it will be understood that when a layer (or film) is referred to as being “on” another layer or substrate, it can be directly on another layer or substrate, or intervening layers may also be present. Further, it will be understood that when a layer is referred to as being “under” another layer, it can be directly under another layer, and one or more intervening layers may also be present. In addition, it will also be understood that when a layer is referred to as being “between” two layers, it can be the only layer between the two layers, or one or more intervening layers may also be present.

As illustrated in example FIG. 1, a method for manufacturing an image sensor in accordance with embodiments can include forming interlayer dielectric layer 130 on and/or over substrate 110 including a plurality of photo diodes 120. Interlayer dielectric layer 130 can be formed having a multi-layer structure including a first interlayer dielectric layer, a light shielding layer for preventing light from being incident on portions other than photodiode 120 region formed on and/or over the first interlayer dielectric layer, and a second interlayer dielectric layer formed on and/or over the light shielding layer. A protective layer for preventing moisture and scratches can then be formed on and/or over interlayer dielectric layer 130.

Color filter layer 140 composed of red (R), green (G) and blue (B ) for filtering light per wavelength band can be formed on and/or over interlayer dielectric layer 130. Color filter layer 140 can be formed by applying a dyeable resist and subjected the resist to exposure and development processes. Planarization layers (PL) 150 for controlling a focal length and ensuring planarity for forming a lens layer can then be formed on and/or over color filter layer 140.

As illustrated in example FIG. 2, oxide film 160 can then be formed on and/or over planarization layer 150. Oxide film 160 may be deposited at a temperature of 200° C. or less and be composed of SiO₂ but is not limited thereto. Oxide film 160 may be formed using CVD, PVD, PECVD, etc.

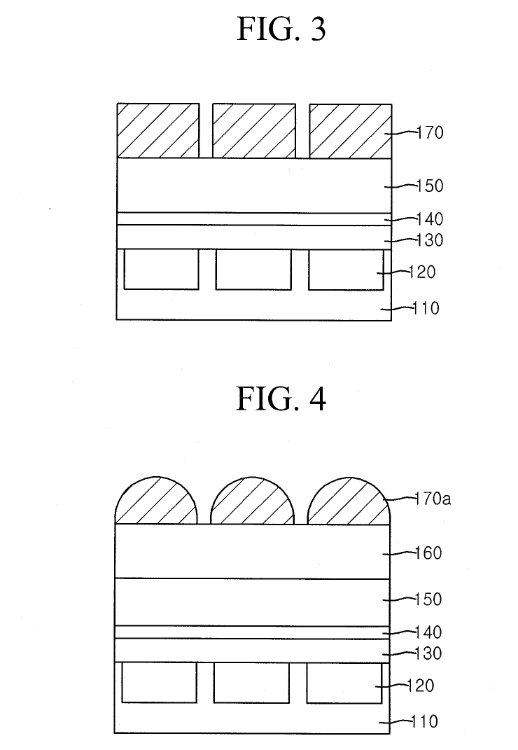

As illustrated in example FIG. 3, a plurality of photo resist patterns 170 spaced apart a predetermined interval can then be formed on and/or over oxide film 160. For example, a photo resist for the micro lens can be applied on and/or over oxide film 160 and then selectively patterned by exposure and development processes using a micro lens mask, thereby forming photo resist pattern 170.

As illustrated in example FIG. 4, oxide film 160 can then be etched using photo resist pattern 170 as an etch mask. Photo resist patterns 170 can be reflowed to form a plurality of micro lens patterns 170a and may etch oxide film 160 using micro lens patterns 170a as etch masks. Semiconductor substrate 110 including photo resist patterns 170 can then be placed on and/or over a hot plate to reflow photo resist patterns 170 by a heat treatment at a temperature of 150° C. or more to form a plurality of hemispherical micro lens patterns 170a. Photo resist pattern 170 can be formed thicker than oxide film 160 since the etch stop ability of photo resist pattern 170 is lower than that of oxide film 160. Likewise, the micro lens pattern 170a can be formed thicker than oxide film 160.

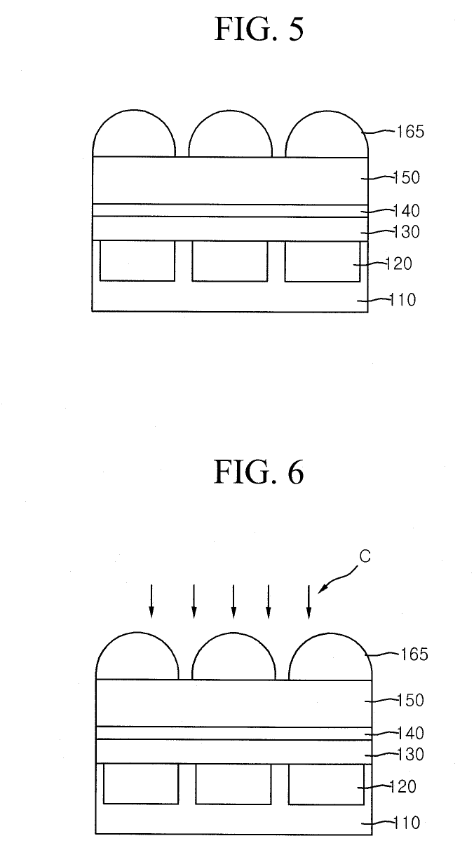

As illustrated in example FIG. 5, a plurality of oxide film micro lenses 165 having a predetermined curvature can then be formed by etching oxide film 160 using micro lens pattern 170a as a mask.

As illustrated in example FIG. 6, micro lens 165 can then be cleaned using a peroxosulfuric acid mixing solution. Embodiments is advantageous for removing residue from the surface of micro lens 165 that remains after patterning oxide micro lens 170a. This can result in the loss of oxide film due to chemicals used to remove the residue of micro lens 165. Therefore, the shape of oxide micro lens 165 can be changed.

Embodiments, however, include a process of cleaning micro lens 165 with a peroxosulfuric acid mixing solution to reduce changes in the shape of oxide film micro lens 165. The use of a peroxosulfuric acid mixing solution can also reduce roughness while easily removing residue from micro lens 165. Micro lens 165 can be cleaned using a peroxosulfuric acid mixing solution with a proportion of H₂O₂:H₂SO₄ being 0.5˜2:6. Micro lens 165 can be cleaned using the peroxosulfuric acid mixing solution at a proportion of H₂O₂:H₂SO₄ is 1:6, but is not limited thereto. Micro lens 165 can be cleaned using a peroxosulfuric acid mixing solution for 3 to 20 minutes. The process of cleaning micro lens 165 with peroxosulfuric acid mixing solution can occur for 5 minutes, but is not limited thereto. Micro lens pattern 170a can be cleaned using a peroxosulfuric acid mixing solution so that the thickness of oxide micro lens 165 can be reduced by no more than 50 Å or less.

Effects of the method for manufacturing the image sensor in accordance with embodiments are as follows. Micro lens 165 can be cleaned with a peroxosulfuric acid mixing solution and then its thickness can be measured to confirm any loss in oxide.

According to the measurement result, the oxide loss of about 32 Å in thickness occurs in the original oxide film micro lens 165 with a radius of about 530 Å, making it possible to obtain oxide micro lens 165 with a radius of about 498 Å. Thus, a method for manufacturing an image sensor using a micro lens composed of an oxide film can be provided.

Moreover, embodiments include a new manufacturing process that removes the photo resist without attacking the oxide micro lens so as not to attack the image sensor, and does not change the shape of the micro lens, making it possible to improve device characteristics.

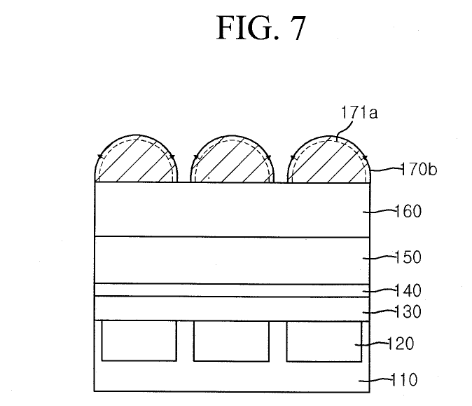

As illustrated in example FIG. 7, a manufacturing process of an image sensor in accordance with embodiments can alternatively include reflowing photo resist pattern 170 to form micro lens pattern 171a and etching oxide film 160 using micro lens pattern 171a as an etch mask to form a plurality of microlenses. Meaning, in accordance with this embodiment, photo resist pattern 171a is reflowed a second time using plasma processing when etching oxide film 160 using micro lens pattern 171a as a mask. Accordingly, such reflow of photo resist pattern 171a can occur in accordance with embodiments using plasma processing to etch oxide film 160 using micro lens pattern 170a as a mask.

For example, oxide film 160 can be primarily etched using micro lens pattern 171a as a mask. Thereafter, micro lens pattern 171a can be subjected to the plasma processing and the primarily etched oxide film 160 can be secondarily etched using the plasma processed micro lens pattern 171a as a mask. The step of performing the plasma processing on micro lens pattern 171a increases source power to 1.5 times or more as large as a proportion of bias power to source power at the primary etch to increase plasma temperature and extend micro lens pattern 171a, making it possible to form the plasma processed micro lens pattern 170b. For example, when the proportion of bias power to source power is 5:1 at the primary etch, the source power can be increased to 1.5 times or more at the primary etch to increase the plasma temperature and extend micro lens pattern 170a, making it possible to form the plasma processed micro lens pattern 170b. For example, in the step of performing the plasma processing on micro lens pattern 170a the bias power may be 200 to 400W and the source power may be 1200 to 1400W.

In the step of forming oxide film micro lens 165 in accordance with embodiments, the plasma processing can also be performed on photo resist pattern 170 or micro lens pattern 170a three times or more and oxide film 160 can be etched using the plasma processed photo resist pattern as the etch mask. The interval between micro lens patterns 170a can thereby be reduced, making it possible to effectively reduce the gap between neighboring oxide micro lenses 165.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing an image sensor comprising:
forming an interlayer dielectric layer on a substrate including a photo diode; and then
forming a color filter layer on the interlayer dielectric layer; and then
forming an oxide film on the color filter layer; and then
forming a plurality of micro lens patterns spaced apart on the oxide film; and then
forming a plurality of oxide micro lenses by etching the oxide film using the micro lens patterns as masks; and then
cleaning the oxide micro lenses using a peroxosulfuric acid mixing solution.

2. The method according to claim 1, wherein the peroxosulfuric acid mixing solution has a proportion of H₂O₂:H₂SO₄ of 0.5˜2:6.

3. The method according to claim 1, wherein cleaning the oxide micro lenses is performed for 3 to 20 minutes.

4. The method according to claim 1, wherein cleaning the oxide micro lenses comprises etching the oxide film micro lens to reduce its thickness by no more than 50 Å or less using the peroxosulfuric acid mixing solution.

5. The method according to claim 1, wherein the micro lens patterns are formed thicker than the oxide film.

6. The method according to claim 1, further comprising, after forming the color filter layer and before forming the oxide film, forming a planarization layer on the color filter layer.

7. The method according to claim 1, wherein forming the oxide film micro lens comprises:
performing a first etching process on the oxide film using the micro lens as the mask; and then
performing plasma processing on the micro lens pattern; and then
performing a second etching process on the oxide film using the plasma processed micro lens pattern as a mask.

8. The method according to claim 7, wherein performing the plasma processing increases source power to 1.5 times or more as large as proportion of bias power to source power at the first etching to increase the plasma temperature and extend the micro lens pattern.

9. The method according to claim 7, wherein during performing the plasma processing the bias power is 200 to 200W and the source power is 1200 to 1400W.

10. The method according to claim 7, wherein the plasma processing is performed on the micro lens pattern three times or more and the oxide film is etched using the plasma processed photo resist pattern as an etch mask.

11. A method of manufacturing an image sensor comprising:
forming an interlayer dielectric layer over a substrate provided with a plurality of photo diodes, the interlayer dielectric layer having a multilayer structure including a first interlayer dielectric layer, a light shielding layer formed over the first interlayer dielectric layer, and a second interlayer dielectric layer formed over the light shielding layer; and then
forming a color filter layer over the interlayer dielectric layer; and then
forming an oxide film over the color filter layer; and then
forming a plurality of photo resist patterns spaced apart over the oxide film; and then
forming a plurality of microlens patterns by reflowing the photo resist patterns and etching the oxide film using the photo resist patterns as masks; and then
forming a plurality of micro lenses composed of an oxide formed spaced apart over the color filter layer by etching the oxide film using the microlens patterns as masks.

12. The method of claim 11, wherein forming the oxide film comprises depositing SiO₂ at a temperature of 200° C. or less by at least one of CVD, PVD and PECVD.

13. The method of claim 11, further comprising, after forming the plurality of oxide film, performing a cleaning process on the micro lenses.

14. The method of claim 13, wherein the micro lenses are cleaned using a peroxosulfuric acid mixing solution.

15. The method of claim 11, wherein during cleaning the micro lenses, the peroxosulfuric acid mixing solution has a proportion of H₂O₂:H₂SO₄ of 0.5˜2:6.

16. The method of claim 11, wherein during cleaning the micro lenses, the peroxosulfuric acid mixing solution has a proportion of H₂O₂:H₂SO₄ of 1:6.

17. The method of claim 11, wherein the micro lenses are cleaned using a peroxosulfuric acid mixing solution for 3 to 20 minutes.

18. The method of claim 11, wherein the thickness of the micro lenses are reduced by no more than 50 Å or less during cleaning the micro lenses.

19. A method of manufacturing an image sensor comprising:
forming an interlayer dielectric layer over a substrate provided with a plurality of photo diodes; and then
forming a color filter layer over the interlayer dielectric layer; and then
forming an oxide film over the color filter layer; and then
forming a plurality of photo resist patterns spaced apart over the oxide film; and then
forming a plurality of microlens patterns by performing a primary etching process on the oxide film using the photo resist patterns as masks; and then
performing plasma processing on the micro lens patterns; and then
forming a plurality of oxide-based micro lenses over the color filter layer performing a secondary etching process on the oxide film using the plasma etched micro lens patterns as masks; and then
performing a cleaning process using a peroxosulfuric acid mixing solution on the oxide-based micro lenses.

20. The method of claim 19, wherein during performing the plasma processing the bias power is 200 to 200W and the source power is 1200 to 1400W.
